(19) United States
(12) Patent Application Publication
(10) Pub. No.: US 2015/0160553 A1
(43) Pub. Date: Jun. 11, 2015

(54) Positive Photosensitive Resin Composition, Photosensitive Resin Film, and Display Device Using the Same

(71) Applicant: Cheil Industries Inc., Gumi-si (KR)

(72) Inventors: Hyo-Young KWON, Uiwang-si (KR); Ran NAMGUNG, Uiwang-si (KR); Jin-Hee KANG, Uiwang-si (KR); Bum-Jin LEE, Uiwang-si (KR); Hwan-Sung CHEON, Uiwang-si (KR)

(73) Assignee: Cheil Industries Inc., Gumi-si (KR)

(21) Appl. No.: 14/291,022

(22) Filed: May 30, 2014

(30) Foreign Application Priority Data
Dec. 5, 2013 (KR) 10-2013-0150809

(51) Int. Cl. G03F 7/039; H05K 5/00

(52) U.S. Cl. CPC G03F 7/039; H05K 5/0017

(57) ABSTRACT

Disclosed are a positive photosensitive resin composition including (A) an alkali soluble resin including a repeating unit represented by the following Chemical Formula 1; (B) a photosensitive diazoquinone compound; and (C) a solvent, and a photosensitive resin film and a display device including the same.

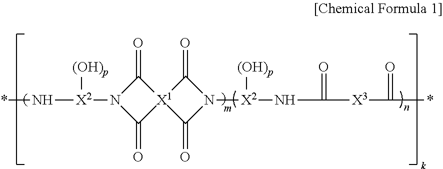

In the above Chemical Formula 1, each substituent is the same as defined in the detailed description.

### CROSS-REFERENCE TO RELATED APPLICATION

This application claims priority to and the benefit of Korean Patent Application No. 10-2013-0150809 filed in the Korean Intellectual Property Office on Dec. 5, 2013, the entire disclosure of which is incorporated herein by reference.

### FIELD OF THE INVENTION

The present invention relates to a positive photosensitive resin composition, and a photosensitive resin film and a display device using the same.

### BACKGROUND OF THE INVENTION

Conventionally, a surface protective layer and an interlayer insulating film for a semiconductor device can use a polyimide resin or a polybenzoxazole resin having excellent heat resistance, electrical characteristics, mechanical characteristics, and the like. These resins have recently been used as a photosensitive polyimide precursor or a polybenzoxazole precursor composition. The compositions are coated on a substrate for a semiconductor or display, patterned by ultraviolet (UV) rays, developed, and thermally cured to form a surface protective layer, an interlayer insulating layer, and the like.

The photosensitive polyimide precursor or polybenzoxazole precursor composition may be applied as a positive type in which an exposed part is developed and dissolved or as a negative type in which the exposed part is cured and maintained. The positive type photosensitive polyimide precursor composition is preferably used, since a non-toxic alkali aqueous solution is used as a development solution.

However, the polyimide precursor composition may not provide the desired pattern, because the carboxylic acid of the polyamic acid is too highly soluble in an alkali aqueous solution. In order to solve this problem, a polyimide precursor can be mixed with a photosensitive diazoquinone compound to decrease dissolution in an alkali aqueous solution. It can still, however, be difficult to obtain a desirable pattern. Also, when an excessive amount of the photosensitive diazoquinone compound is used, solubility for an alkali aqueous solution can be significantly reduced and thus developability can be deteriorated.

In addition, a material can be prepared by replacing the carboxylic acid with phenolic hydroxyl acid for example, esterificating the polyamidic acid with an alcohol compound having at least one hydroxyl group (Japanese Patent Laid-Open Pyong 10-307393). This material, however, can be insufficiently developed and can cause film loss or result in resin delamination from a substrate.

Recently, another material prepared by mixing the polybenzoxazole precursor with a diazonaphthoquinone compound has drawn attention (Japanese Patent Laid-open Sho 63-96162). However, when actually used as the polybenzoxazole precursor composition, film loss of a non-exposed part can be remarkably increased so that the desirable pattern cannot be obtained after development.

In order to improve this problem, if the molecular weight of the polybenzoxazole precursor is increased, the film loss of the non-exposed part can be reduced. A residue (a scum), however, can be generated during the development, which can deteriorate resolution and increase development time of the exposed part.

Therefore, there have been attempts to develop an alkali soluble resin having improved film residue ratio, sensitivity, and the like in which a photosensitive diazoquinone compound is not used excessively.

### SUMMARY OF THE INVENTION

One embodiment of the present invention provides a positive photosensitive resin composition that can have high sensitivity, and a low film decreasing ratio after curing due to improved curing of an alkali soluble resin.

Another embodiment of the present invention provides a photosensitive resin film prepared using the positive photosensitive resin composition.

Yet another embodiment of the present invention provides a display device including the photosensitive resin film.

One embodiment of the present invention provides a positive photosensitive resin composition including (A) an alkali soluble resin including a repeating unit represented by the following Chemical Formula 1; (B) a photosensitive diazoquinone compound; and (C) a solvent.

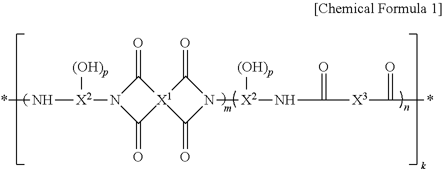

In the above Chemical Formula 1,

X¹, X² and X³ are the same or different and are each independently an aromatic organic group, a divalent to octavalent aliphatic organic group, or a divalent to octavalent alicyclic organic group,

m and n are the same or different and are each independently integers of 1 to 10,

k is an integer of 1 to 10,000, and

p is an integer of 0 to 6.

In the above Chemical Formula 1, m and n may be independently integers of 1 or 2.

The alkali soluble resin may be an alternating copolymer, a block copolymer, a random copolymer of polyimide-polyhydroxyamide, or a combination thereof.

The alkali soluble resin may be an alternating copolymer of polyimide-polyhydroxyamide.

The alkali soluble resin may have a weight average molecular weight of about 1,000 g/mol to about 20,000 g/mol.

The solvent may be N-methyl-2-pyrrolidone, γ-butyrolactone, N,N-dimethylacetamide, dimethylsulfoxide, diethylene glycoldimethylether, diethylene glycoldiethylether, diethylene glycoldibutylether, propylene glycolmonomethylether, dipropylene glycolmonomethylether, propylene glycolmonomethyl ether acetate, methyllactate, ethyllactate, butyllactate, methyl-1,3-butylene glycolacetate, 1,3-butylene glycol-3-monomethylether, methylpyruvate, ethylpyruvate, methyl-3-methoxy propionate, or a combination thereof.

The positive photosensitive resin composition may further include an additive selected from a surfactant, a leveling agent, a thermal acid generator, and a combination thereof.

The positive photosensitive resin composition may include about 5 parts by weight to about 100 parts by weight of the photosensitive diazoquinone compound (B) and about 200 parts by weight to about 900 parts by weight of the solvent (C) based on about 100 parts by weight of the alkali soluble resin (A).

Another embodiment of the present invention provides a photosensitive resin film prepared using the positive photosensitive resin composition.

Yet another embodiment of the present invention provides a display device including the photosensitive resin film.

Other embodiments of the present invention are included in the following detailed description.

The photosensitive resin composition can have an improved dissolution force for an alkali aqueous solution, and improved sensitivity, film residue ratio, chemical resistance and reliability, and a photosensitive resin film prepared using the photosensitive resin composition may be used for a display device.

### DETAILED DESCRIPTION

The present invention now will be described more fully hereinafter in the following detailed description of the invention, in which some, but not all embodiments of the invention are described. Indeed, this invention may be embodied in many different forms and should not be construed as limited to the embodiments set forth herein; rather, these embodiments are provided so that this disclosure will satisfy applicable legal requirements.

As used herein, when a specific definition is not otherwise provided, the term “substituted” refers to one substituted with at least one substituent including a halogen atom (F, Cl, Br, or I), a hydroxy group, a nitro group, a cyano group, an amino group (NH₂, NH(R²⁰⁰) or N(R²⁰¹)(R²⁰²), wherein R²⁰⁰, R²⁰¹ and R²⁰² are the same or different and are each independently C1 to C10 alkyl), an amidino group, a hydrazine group, a hydrazone group, a carboxyl group, substituted or unsubstituted C1 to C30 alkyl, substituted or unsubstituted C2 to C30 alkenyl, substituted or unsubstituted C2 to C30 alkynyl, substituted or unsubstituted C6 to C30 aryl, substituted or unsubstituted C3 to C30 cycloalkyl, substituted or unsubstituted C2 to C30 heteroaryl, substituted or unsubstituted C2 to C30 heterocycloalkyl, or a combination thereof, in place of at least one hydrogen of a functional group.

As used herein, when a specific definition is not otherwise provided, the term “alkyl” refers to C1 to C30 alkyl, for example C1 to C20 alkyl, the term “cycloalkyl” refers to C3 to C30 cycloalkyl, for example C3 to C20 cycloalkyl, the term “alkoxy” refers to C1 to C30 alkoxy, for example C1 to C18 alkoxy, the term “aryl” refers to C6 to C30 aryl, for example C6 to C20 aryl, the term “alkenyl” refers to C2 to C30 alkenyl, for example C2 to C18 alkenyl, the term “alkylene” refers to C1 to C30 alkylene, for example C1 to C18 alkylene, and the term “arylene” refers to C6 to C30 arylene, for example C6 to C16 arylene.

As used herein, when a specific definition is not otherwise provided, the term “aliphatic organic group” refers to C1 to C30 alkyl, C2 to C30 alkenyl, C2 to C30 alkynyl, C1 to C30 alkylene, C2 to C30 alkenylene, or C2 to C30 alkynylene, for example C1 to C15 alkyl, C2 to C15 alkenyl, C2 to C15 alkynyl, C1 to C15 alkylene, C2 to C15 alkenylene, or C2 to C15 alkynylene, the term “alicyclic organic group” refers to C3 to C30 cycloalkyl, C3 to C30 cycloalkenyl, C3 to C30 cycloalkynyl, C3 to C30 cycloalkylene, C3 to C30 cycloalkenylene, or C3 to C30 cycloalkynylene, for example C3 to C15 cycloalkyl, C3 to C15 cycloalkenyl, C3 to C15 cycloalkynyl, C3 to C15 cycloalkylene, C3 to C15 cycloalkenylene, or C3 to C15 cycloalkynylene, the term “aromatic organic group” refers to C6 to C30 aryl or C6 to C30 arylene, for example C6 to C16 aryl or C6 to C16 arylene, the term “heterocyclic group” refers to C2 to C30 heterocycloalkyl, C2 to C30 heterocycloalkylene, C2 to C30 heterocycloalkenyl, C2 to C30 heterocycloalkenylene, C2 to C30 heterocycloalkynyl, C2 to C30 heterocycloalkynylene, C2 to C30 heteroaryl, or C2 to C30 heteroarylene that include 1 to 3 hetero atoms including O, S, N, P, Si, or a combination thereof, in a ring, for example C2 to C15 heterocycloalkyl, C2 to C15 heterocycloalkylene, C2 to C15 heterocycloalkenyl, C2 to C15 heterocycloalkenylene, C2 to C15 heterocycloalkynyl, C2 to C15 heterocycloalkynylene, C2 to C15 heteroaryl, or C2 to C15 heteroarylene that include 1 to 3 hetero atoms including O, S, N, P, Si, or a combination thereof, in a ring.

As used herein, when a specific definition is not otherwise provided, the terms “fluoroalkyl group”, “fluoroalkylene group”, “fluorocycloalkylene group”, “fluoroarylene group”, “fluoroalkoxy group” and “fluoroalcohol group” are independently an alkyl group, an alkylene group, a cycloalkylene group, an arylene group, an alkoxy group and an alcohol group, respectively, that include a fluorine atom-containing substituent without limitation.

As used herein, unless a specific definition is otherwise provided, a hydrogen atom is bonded at a position when a chemical bond is not drawn where a bond would otherwise appear.

As used herein, when a specific definition is not otherwise provided, the term “combination” refers to mixing or copolymerization.

Also, “*” refers to a linking part between the same or different atoms, or chemical formulae.

One embodiment of the present invention provides a positive photosensitive resin composition including (A) an alkali soluble resin including a repeating unit represented by the following Chemical Formula 1; (B) a photosensitive diazoquinone compound; and (C) a solvent.

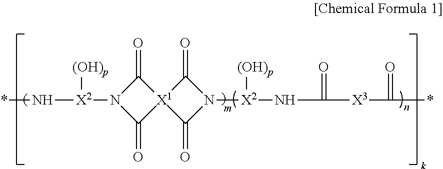

In the above Chemical Formula 1,

X¹, X² and X³ are the same or different and are each independently an aromatic organic group, a divalent to octavalent aliphatic organic group, or a divalent to octavalent alicyclic organic group,

m and n are the same or different and are each independently integers of 1 to 10,

k is an integer of 1 to 10,000, and

p is an integer of 0 to 6.

The alkali soluble resin can include a polyimide repeating unit having no carboxyl group other than a polyhydroxyamide repeating unit and thus, solubility in an alkali aqueous solution may be adjusted. In addition, since a polyimide repeating unit having a ring-closure is included therein, the problem of decreasing chemical resistance and reliability due to low ring-closure of a polyhydroxyamide repeating unit after curing may be solved. In addition, since the polyimide repeating unit has already been ring-closed, a photosensitive diazoquinone compound deteriorating dissolution in an alkali aqueous solution need not be used in an excessive amount, and thus, sensitivity may be improved during exposure.

Hereinafter, each component of the positive photosensitive resin composition is described in detail.

### (A) Alkali Soluble Resin

An alkali soluble resin that is one constituent component of the positive photosensitive resin composition according to one embodiment includes the repeating unit represented by the above Chemical Formula 1, and thus may improve sensitivity, a film residue ratio, and the like of a photosensitive resin film prepared from the alkali soluble resin.

The alkali soluble resin may be an alternating copolymer, a block copolymer, a random copolymer of polyimide-polyhydroxyamide, or a combination thereof.

For example the alkali soluble resin may be an alternating copolymer of polyimide-polyhydroxyamide.

When the alkali soluble resin is present as an alternating copolymer, sensitivity, film residue ratio, and the like as well as optical characteristics and mechanical properties may be further improved.

In the above Chemical Formula 1 X¹ may be an aromatic organic group, a divalent to octavalent aliphatic organic group, or a divalent to octavalent alicyclic organic group. For example, the aromatic organic group or divalent to octavalent alicyclic organic group may be a residual group derived from tetracarboxylic acid dianhydride. X¹ may be, for example, cyclopentane, cyclohexane, cycloheptane, cyclooctane, cyclononane, cyclodecane, bicyclopentane, bicyclohexane, bicycloheptane, bicyclooctane, bicyclononane, bicyclodecane, benzene, naphthalene, biphenyl, dimethylbiphenyl, diphenylether, diphenylthioether, diphenylsulfone, diphenylpropane, diphenyl-1,1,1,3,3,3-hexafluoropropane, benzophenone, and the like. Examples of the tetracarboxylic acid dianhydride being capable of forming this residual group may be represented by one or more of the following Chemical Formulae 2 to 9, but are not limited thereto.

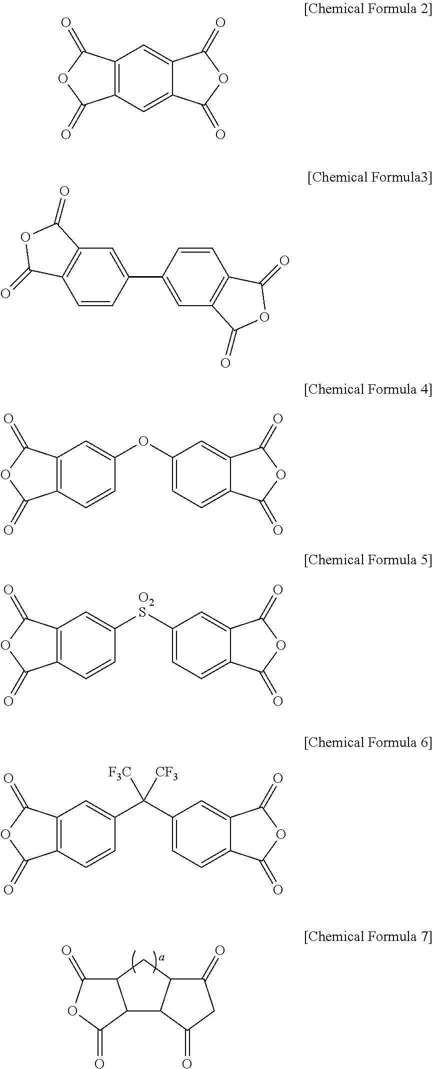

In the above Chemical Formula 7, a is an integer of 1 to 6.

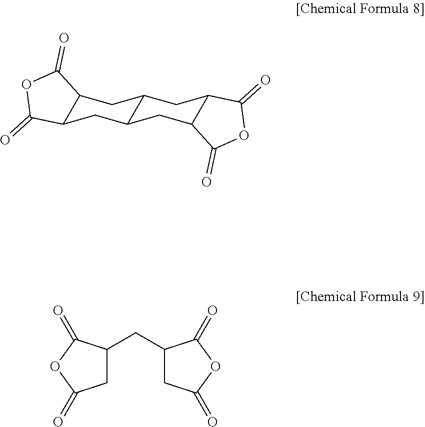 [SMILES: O=C1OC(=O)C2CC3CC4C(=O)OC(=O)C4CC3CC12 ; O=C1CC(CC2CC(=O)OC2=O)C(=O)O1]

In the above Chemical Formula 1, X² and X³ are the same or different and each may be an aromatic organic group, a divalent to octavalent aliphatic organic group, or a divalent to octavalent alicyclic organic group. Examples include without limitation 3,3′-diamino-4,4′-dihydroxybiphenyl, 4,4′-diamino-3,3′-dihydroxybiphenyl, bis(3-amino-4-hydroxyphenyl)propane, bis(4-amino-3-hydroxyphenyl)propane, bis(3-amino-4-hydroxyphenyl)sulfone, bis(4-amino-3-hydroxyphenyl)sulfone, 2,2-bis(3-amino-4-hydroxyphenyl)-1,1,1,3,3,3-hexafluoropropane, 2,2-bis(4-amino-3-hydroxyphenyl)-1,1,1,3,3,3-hexafluoropropane, and the like, and combinations thereof.

For example, in the above Chemical Formula 1,

X² may be the following Chemical Formula 10, Chemical Formula 10-1, Chemical Formula 11, or Chemical Formula 11-1,

X³ may be the following Chemical Formula 10-1, Chemical Formula 11-1, Chemical Formula 12, Chemical Formula 13, Chemical Formula 14 or Chemical Formula 15,

p may be an integer of 2, and

m and n are independently integers of 1 or 2.

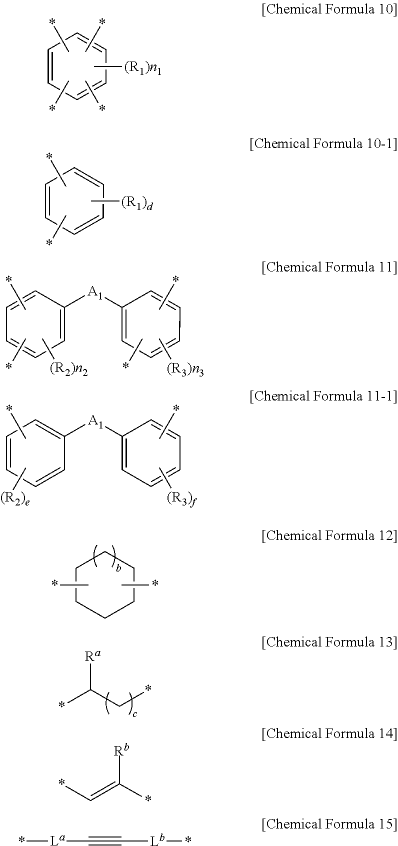

In the above Chemical Formulae 10 to 15,

A₁ is O, CO, CR⁸R⁹ (wherein R⁸ and R⁹ are the same or different and are each independently hydrogen or substituted or unsubstituted alkyl, for example a fluoroalkyl group), SO₂, S, or a single bond,

R₁, R₂, R₃ are the same or different and are each independently hydrogen, substituted or unsubstituted alkyl, a hydroxy group, a carboxyl group, or a thiol group,

n1 is an integer of 1 to 2,

n2 and n3 are the same or different and are each independently integers of 1 to 3,

b and c are the same or different and are each independently integers of 1 to 6,

d, e and f are the same or different and are each independently integers of 1 to 4,

R^{a} and R^{b} are the same or different and are each independently hydrogen, a hydroxy group, or substituted or unsubstituted C1 to C10 alkyl, and

L^{a} and L^{b} are the same or different and are each independently a single bond, substituted or unsubstituted C2 to C10 alkylene, substituted or unsubstituted C3 to C10 cycloalkylene, substituted or unsubstituted C2 to C10 arylene, or substituted or unsubstituted C2 to C10 heteroarylene.

Examples of X² and X³ may include without limitation one or more of the following Chemical Formula 16 to Chemical Formula 21 (Chemical Formulae 16, 16-1, 16-2, 16-3, 17, 17-1, 17-2, 17-3, 18, 18-1, 18-2, 18-3, 19, 19-1, 19-2, 19-3, 20, 20-1, 20-2, 20-3, 21, 21-1, 21-2, and/or 21-3).

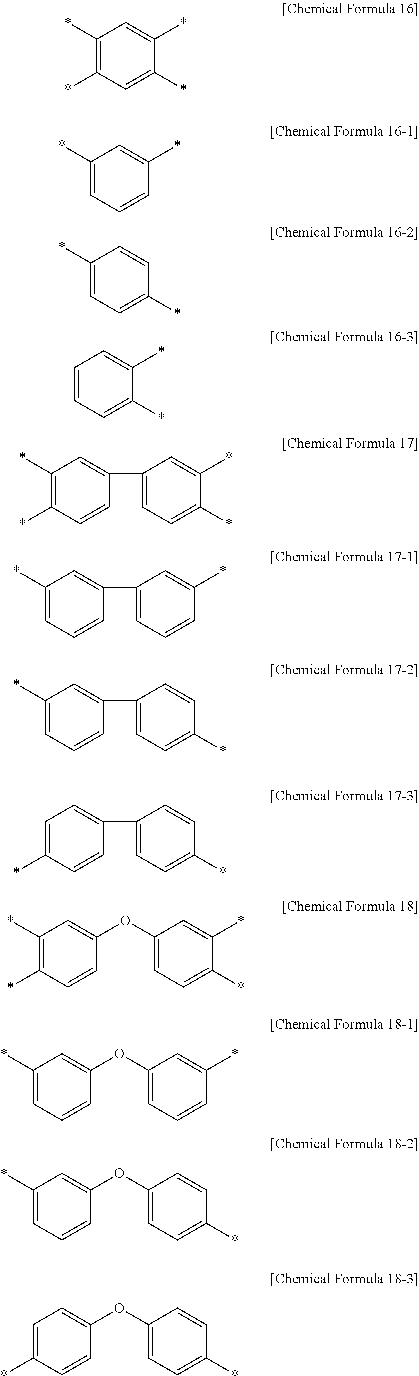

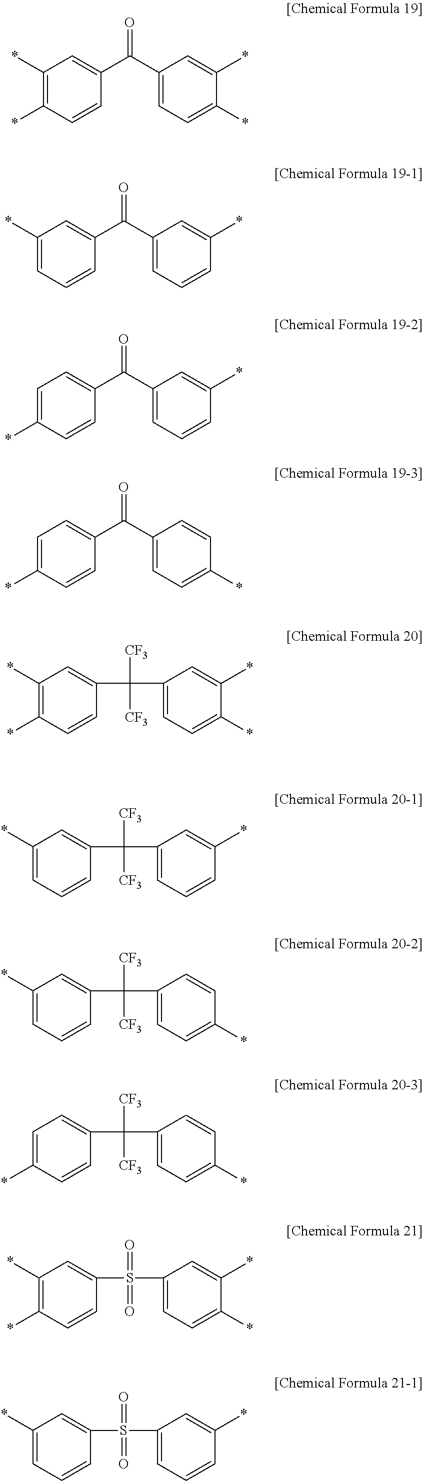

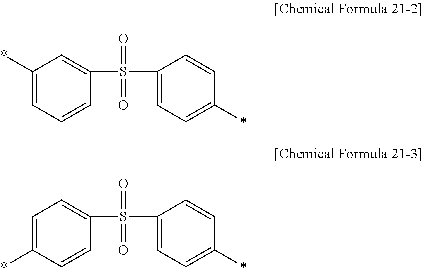 [SMILES: *c1ccc(S(=O)(=O)c2cccc(*)c2)cc1 ; *c1ccc(S(=O)(=O)c2ccc(*)cc2)cc1]

The alkali soluble resin may have a weight average molecular weight (Mw) of about 1,000 g/mol to about 100,000 g/mol, for example about 3,000 g/mol to about 20,000 g/mol. When the alkali soluble resin has a weight average molecular weight within the above range, the composition may provide sufficient film residue ratios at non-exposed parts during development using an alkali aqueous solution, and patterning may be performed efficiently.

### (B) Photosensitive Diazoquinone Compound

The photosensitive diazoquinone compound may be a compound having a 1,2-benzoquinone diazide structure and/or 1,2-naphthoquinone diazide structure.

The photosensitive diazoquinone compound may include at least one or more compounds represented by the following Chemical Formulae 26 and 28 to 30, but is not limited thereto.

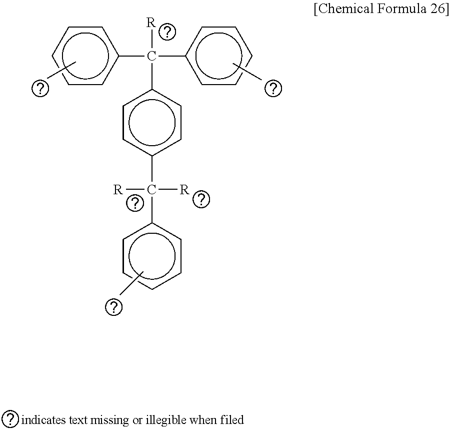

In the above Chemical Formula 26,

R₃₁ to R₃₃ are the same or different and are each independently, hydrogen or substituted or unsubstituted alkyl, for example CH₃,

D₃ are the same or different and are each independently OQ, where the Q is hydrogen or the following Chemical Formula 27a or 27b, provided that all Qs are not simultaneously hydrogen, and

n31 to n33 are the same or different and are each independently integers of 1 to 3.

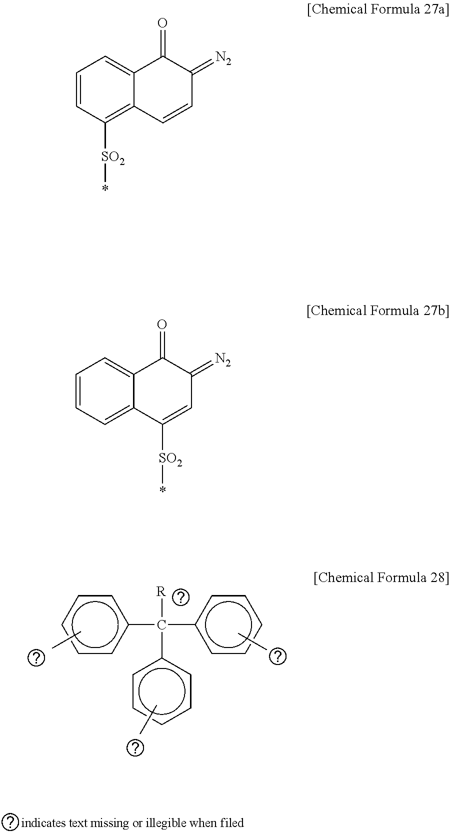

In the above Chemical Formula 28,

R₃₄ may be hydrogen or substituted or unsubstituted alkyl,

D₄ to D₆ are the same or different and are each independently OQ, where the Q is the same as defined in the above Chemical Formula 26, and

n34 to n36 are the same or different and are each independently integers of 1 to 3.

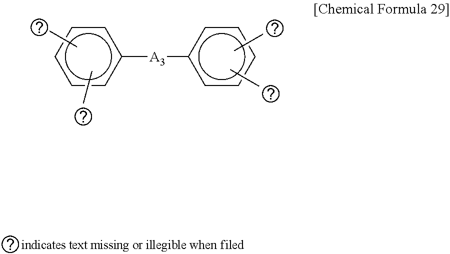

In the above Chemical Formula 29,

A₃ may be CO or CR⁵⁰⁰R⁵⁰¹, wherein R⁵⁰⁰ and R⁵⁰¹ are the same or different and are each independently substituted or unsubstituted alkyl,

D₇ to D₁₀ are the same or different and are each independently hydrogen, substituted or unsubstituted alkyl, OQ, or NHQ, where the Q is the same as defined in the above Chemical Formula 26,

n37, n38, n39 and n40 are the same or different and are each independently integers of 0 to 4,

n37+n38 and n39+n40 are the same or different and are each independently integers of less than or equal to 5, and

at least one of the D₇ to D₁₀ may be OQ, and one aromatic ring includes one to three OQs and the other aromatic ring includes one to four OQs.

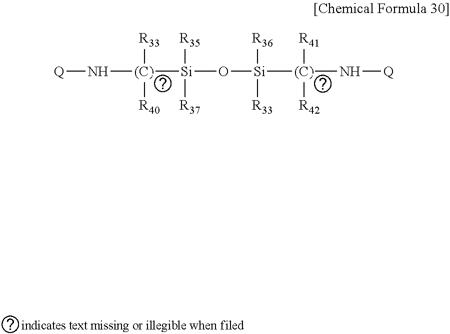

In the above Chemical Formula 30,

R₃₅ to R₄₂ are the same or different and are each independently, hydrogen or substituted or unsubstituted alkyl,

n41 and n42 are the same or different and are each independently integers of 1 to 5, for example 2 to 4, and

Q is the same as defined in the above Chemical Formula 26.

The positive photosensitive resin composition may include the photosensitive diazoquinone compound in an amount of about 5 parts by weight to about 100 parts by weight based on about 100 parts by weight of the alkali soluble resin (A). In some embodiments, the positive photosensitive resin composition may include the photosensitive diazoquinone compound in an amount of about 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, or 100 parts by weight. Further, according to some embodiments of the present invention, the amount of the photosensitive diazoquinone compound can be in a range from about any of the foregoing amounts to about any other of the foregoing amounts.

When the photosensitive diazoquinone compound is included in an amount within the above range, the pattern can be well-formed with minimal or no residue from exposure, and film thickness loss during development may be prevented and thereby a good pattern can be provided.

### (C) Solvent

The positive photosensitive resin composition may include a solvent that is capable of easily dissolving each component.

The solvent may be an organic solvent. Examples of the solvent may include without limitation N-methyl-2-pyrrolidone, gamma-butyrolactone, N,N-dimethylacetamide, dimethylsulfoxide, diethylene glycoldimethylether, diethylene glycoldiethylether, diethylene glycoldibutylether, propylene glycolmonomethylether, dipropylene glycolmonomethylether, propylene glycolmonomethyl ether acetate, methyl lactate, ethyl lactate, butyl lactate, methyl-1,3-butylene glycol acetate, 1,3-butylene glycol-3-monomethylether, methyl pyruvate, ethyl pyruvate, methyl-3-methoxy propionate, and the like, and combinations thereof.

The solvent may be selected appropriately depending on a process of forming a photosensitive resin film such as spin coating, slit die coating, and the like.

The positive photosensitive resin composition may include the solvent in an amount of about 200 parts by weight to about 900 parts by weight, for example about 200 parts by weight to about 700 parts by weight, based on about 100 parts by weight of the alkali soluble resin (A).

When the positive photosensitive resin composition includes the solvent in an amount within the above range, a sufficiently thick film may be obtained, and good solubility and coating properties may be provided.

### (D) Other Additives

The positive photosensitive resin composition according to one embodiment may further include one or more other additives.

The other additives may be a thermal acid generator. Examples of the thermal acid generator may include without limitation arylsulfonic acids such as p-toluenesulfonic acid, benzenesulfonic acid, and the like, perfluoroalkylsulfonic acids such as trifluoromethanesulfonic acid, trifluorobutanesulfonic acid, and the like, alkylsulfonic acids such as methanesulfonic acid, ethanesulfonic acid, butanesulfonic acid, and the like, and the like, and combinations thereof.

The thermal acid generator is a catalyst for a dehydration reaction and a cyclization reaction of polyamide including a phenolic hydroxy group of the alkali soluble resin, and thus a cyclization reaction may be performed smoothly even if a curing temperature is decreased.

In addition, an additive such as a suitable surfactant and/or leveling agent may be included in order to prevent a stain of the film and/or to improve development.

The thermal acid generator, surfactant, and/or leveling agent may be used singularly or as a mixture.

A patterning process using the positive photosensitive resin composition may include coating the positive photosensitive resin composition on a support substrate in a method of spin coating, slit coating, inkjet printing, and the like; drying the coated positive photosensitive resin composition to form a positive photosensitive resin composition film; exposing the positive photosensitive resin composition film to light; developing the exposed positive photosensitive resin composition film in an alkali aqueous solution to obtain a photosensitive resin film; and heat-treating the photosensitive resin film. Conditions for the patterning process are well known in a related art and will not be illustrated in detail in the specification.

According to another embodiment, a photosensitive resin film prepared using the positive photosensitive resin composition is provided. The photosensitive resin film may be, for example an organic insulation layer.

According to yet another embodiment of the present invention, a display device including the photosensitive resin film is provided. The display device may be an organic light emitting diode (OLED) or a liquid crystal display (LCD).

Hereinafter, the present invention is illustrated in more detail with reference to the following examples and comparative examples. However, the following examples and comparative examples are provided for the purpose of descriptions and the present invention is not limited thereto.

### EXAMPLE

### Synthesis of Alkali Soluble Resin

### Synthesis Example 1

### Synthesis of Polyimide-Polyhydroxyamide Copolymer

21.28 g of 2,2′-bis(3-amino-4-hydroxyphenyl)hexafluoropropane (BHAF) and 3.8 g of 5-norbornene-2,3-dicarboxylic acid anhydride are dissolved in 104 g of N-methyl-2-pyrrolidone (NMP) in a 4-necked flask having an agitator, a temperature controller, a nitrogen gas injector, and a cooler while nitrogen gas is passed through the flask. When the solids are completely dissolved, 3.6 g of pyridine is added thereto, and the mixture is heated up to 80° C. and agitated for 5 hours. Subsequently, the reactant is maintained at 80° C., and a solution obtained by dissolving 10.3 g of 5,5′-(perfluoropropane-2,2-diyl)diisobenzofuran-1,3-dione in 41 g of N-methyl-2-pyrrolidone (NMP) is slowly added thereto for 30 minutes. After the addition, the obtained mixture is reacted at 90° C., agitated for 10 hours, and cooled down to room temperature. Then, the temperature is decreased to 0 to 5° C., 4 g of pyridine is added to the reactant, and a solution obtained by dissolving 6.85 g of 4,4′-dioxybenzoyl chloride in 27.44 g of N-methyl-2-pyrrolidone (NMP) is slowly added thereto for 30 minutes. After the addition, the mixture is reacted at 0 to 5° C. for 2 hours, heated up to room temperature, and agitated for 1 hour, completing the reaction. The reaction mixture is put in water to produce a precipitate, the precipitate is filtered and sufficiently washed with water, and dried at 80° C. for greater than or equal to 24 hours, obtaining a copolymer represented by the following Chemical Formula 41. A weight average molecular weight of the polymer reduced to standard polystyrene by a GPC method is 6,600 g/mol, and polydispersity of the polymer is 1.65.

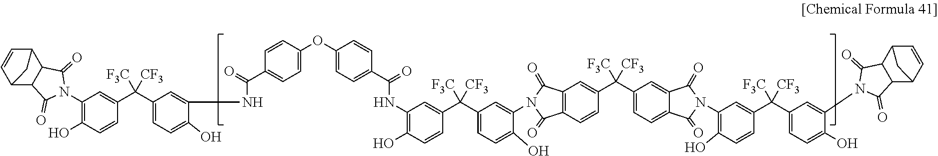

### Synthesis Example 2

### Synthesis of Polyimide-Polyhydroxyamide Copolymer

21.02 g of 2,2′-bis(3-amino-4-hydroxyphenyl)hexafluoropropane (BHAF) and 2.82 g of 5-norbornene-2,3-dicarboxylic acid anhydride are dissolved in 111 g of N-methyl-2-pyrrolidone (NMP) in a 4-necked flask having an agitator, a temperature controller, a nitrogen gas injector, and a cooler while nitrogen gas is passed through the flask. When the solids are completely dissolved, 3.86 g of pyridine is added thereto, and the mixture is heated up to 80° C. and agitated for 5 hours. Subsequently, the reactant is maintained at 80° C., and a solution obtained by dissolving 10.84 g of 5,5′-(perfluoropropane-2,2-diyl)diisobenzofuran-1,3-dione and 43 g of N-methyl-2-pyrrolidone (NMP) is slowly added thereto for 30 minutes. After the addition, the mixture is reacted at 90° C., agitated for 10 hours, and then, cooled down to room temperature. Then, the temperature is increased up to 0 to 5° C., 4.24 g of pyridine is additionally added to the solution, and a solution obtained by dissolving 7.2 g of 4,4′-dioxybenzoylchloride in 28.8 g of N-methyl-2-pyrrolidone (NMP) is slowly added thereto for 30 minutes. After the addition, the mixture is reacted for 2 hours at a temperature of 0 to 5° C., heated up to room temperature, and then, agitated for 1 hour, completing the reaction. The reaction mixture is put in water to produce a precipitate, and the precipitate is filtered, sufficiently washed with water, and dried at 80° C. under vacuum for greater than or equal to 24 hours, obtaining a copolymer. A weight average molecular weight of the polymer reduced to standard polystyrene by a GPC method is 7,700 g/mol, and polydispersity of the polymer is 1.63.

### Synthesis Example 3

### Synthesis of Polyimide-Polyhydroxyamide Copolymer

A copolymer represented by the following Chemical Formula 42 is manufactured according to the same method as Synthesis Example 1 except for using 4.46 g of trimellitic anhydride instead of 3.8 g of the 5-norbornene-2,3-dicarboxylic acid anhydride in Synthesis Example 1. Herein, a weight average molecular weight of the copolymer reduced to standard polystyrene by a GPC method is 6,600 g/mol, and polydispersity of the copolymer is 1.64.

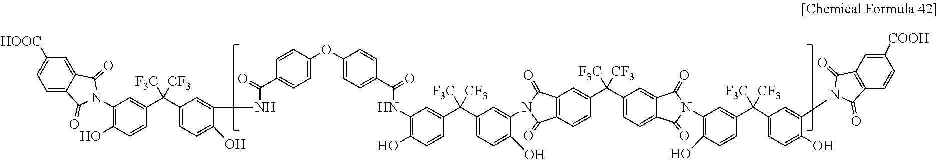

### Synthesis Example 4

### Synthesis of Polyimide-Polyhydroxyamide Copolymer

A copolymer is manufactured according to the same method as Synthesis Example 2 except for using 3.3 g of trimellitic anhydride instead of 2.82 g of the 5-norbornene-2,3-dicarboxylic acid anhydride in Synthesis Example 2. Herein, a weight average molecular weight of the copolymer reduced to standard polystyrene by a GPC method is 8,200 g/mol, and polydispersity of the copolymer is 1.62.

### Synthesis Example 5

### Synthesis of Polyimide-Polyhydroxyamide Copolymer

A copolymer represented by the following Chemical Formula 43 is manufactured according to the same method as Synthesis Example 1 except for dissolving 5.2 g of 5,5′-(perfluoropropane-2,2-diyl)diisobenzofuran-1,3-dione in 20 g of N-methyl-2-pyrrolidone (NMP) and slowly adding a solution obtained by dissolving 10.3 g of 4,4′-dioxybenzoylchloride in 41 g of N-methyl-2-pyrrolidone (NMP) in a dropwise fashion for 30 minutes in Synthesis Example 1. Herein, a weight average molecular weight of the copolymer reduced to standard polystyrene by a GPC method is 6,900 g/mol, and polydispersity of the polymer is 1.67.

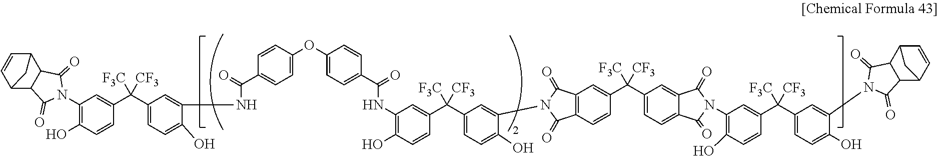

### Synthesis Example 6

### Synthesis of Polyimide-Polyhydroxyamide Copolymer

A copolymer represented by the following Chemical Formula 44 is manufactured according to the same method as Synthesis Example 1 except for dissolving 15.3 g of 5,5′-(perfluoropropane-2,2-diyl)diisobenzofuran-1,3-dione in 61 g of N-methyl-2-pyrrolidone (NMP) and slowly adding a solution obtained by dissolving 3.4 g of 4,4′-dioxybenzoylchloride in 14 g of N-methyl-2-pyrrolidone (NMP) in a dropwise fashion for 30 minutes in Synthesis Example 1. Herein, a weight average molecular weight of the copolymer reduced to standard polystyrene by a GPC method is 6,400 g/mol, and polydispersity of the copolymer is 1.64.

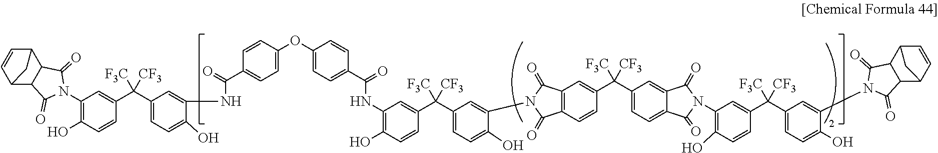

### Comparative Synthesis Example 1

18.7 g of 2,2′-bis(3-amino-4-hydroxyphenyl)hexafluoropropane (BHAF) and 3.35 g of 5-norbornene-2,3-dicarboxylic acid anhydride are dissolved in 117 g of N-methyl-2-pyrrolidone (NMP) in a 4-necked flask having an agitator, a temperature controller, a nitrogen gas injector, and a cooler while nitrogen gas is passed through the flask. When the solids are completely dissolved, 7.3 g of pyridine is added thereto, and the mixture is heated up to 50° C. and agitated for 5 hours. Subsequently, the temperature is decreased down to 0 to 5° C., and a solution obtained by dissolving 12.35 g of 4,4′-dioxybenzoylchloride in 30.49 g of N-methyl-2-pyrrolidone (NMP) are slowly added thereto in a dropwise fashion for 30 minutes. After the addition, the mixture is reacted for 1 hour at a temperature 0 to 5° C., heated up to room temperature, and then, agitated for 1 hour, completing the reaction. The reaction mixture is put in water to produce a precipitate, and the precipitate is filtered, sufficiently washed with water, and dried at 80° C. for greater than or equal to 24 hours under vacuum, obtaining an alkali soluble resin including a polyhydroxy amide repeating unit represented by the following Chemical Formula 45. Herein, a weight average molecular weight of the alkali soluble resin to reduced standard polystyrene by a GPC method is 7,000 g/mol, and polydispersity of the alkali soluble resin is 1.63.

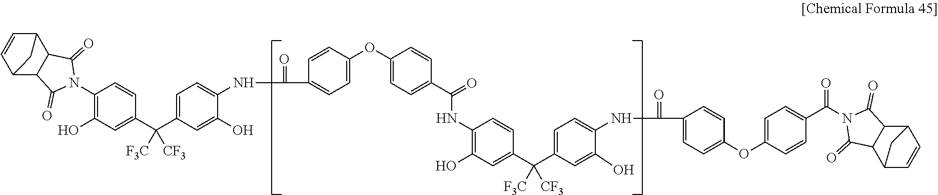

### Comparative Synthesis Example 2

31.9 g of 4,4′-oxydianiline and 10.5 g of 5-norbornene-2,3-dicarboxylic acid anhydride are dissolved in 168 g of N-methyl-2-pyrrolidone (NMP) in a 4-necked flask having an agitator, a temperature controller, a nitrogen gas injector, and a cooler while nitrogen gas is passed through the flask. Herein, the obtained solution includes a solid content of 15 wt %.

When the solid is completely dissolved, 25.2 g of pyridine is added thereto, and the mixture is heated up to 80° C. and agitated for 5 hours. Then, the reactant is maintained at the temperature of 80° C., and a solution obtained by dissolving 56.67 g of 5,5′-(perfluoropropane-2,2-diyl)diisobenzofuran-1,3-dione in 226 g of N-methyl-2-pyrrolidone (NMP) is slowly added thereto in a dropwise fashion for 30 minutes. After the addition, the mixture is reacted at 80° C. and agitated for 10 hours and then, cooled down to room temperature. The reaction mixture is put in water to produce a precipitate, and the precipitate is filtered, sufficiently washed with water, and dried at 80° C. under vacuum for greater than or equal to 24 hours, obtaining an alkali soluble resin including a polyimide repeating unit represented by the following Chemical Formula 46. Herein, a weight average molecular weight of the alkali soluble resin reduced to standard polystyrene by a GPC method is 7,800 g/mol, and polydispersity of the alkali soluble resin is 1.63.

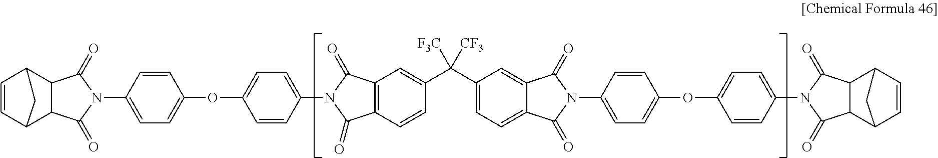

### Comparative Synthesis Example 3

19.8 g of 2,2′-bis (3-amino-4-hydroxyphenyl)hexafluoropropane (BHAF) and 3.5 g of 5-norbornene-2,3-dicarboxylic acid anhydride are dissolved in 51 g of N-methyl-2-pyrrolidone (NMP) in a 4-necked flask having an agitator, a temperature controller, a nitrogen gas injector, and a cooler while nitrogen gas is passed through the flask. When the solids are completely dissolved, 1.7 g of pyridine is added thereto, and the mixture is heated up to 80° C. and agitated for 3 hours. Subsequently, the temperature is cooled down to room temperature, a solution obtained by dissolving 9.63 g of 5,5′-(perfluoropropane-2,2-diyl)diisobenzofuran-1,3-dione in 38 g of N-methyl-2-pyrrolidone (NMP) is slowly added thereto for 30 minutes. After the addition, the mixture is reacted at room temperature for 2 hours, the reaction solution is heated up to 90° C. and agitated for 10 hours. When a polyimide repeating unit is formed in the reaction, water is put in the reaction mixture to produce a precipitate, and the precipitate is filtered and sufficiently washed with water and then, dried at 80° C. under vacuum for greater than or equal to 24 hours, obtaining an alkali soluble resin including a polyamic acid a repeating unit represented by the following Chemical Formula 47. Herein, a weight average molecular weight of the alkali soluble resin reduced to standard polystyrene by a GPC method is 7,300 g/mol, and polydispersity of the alkali soluble resin is 1.65.

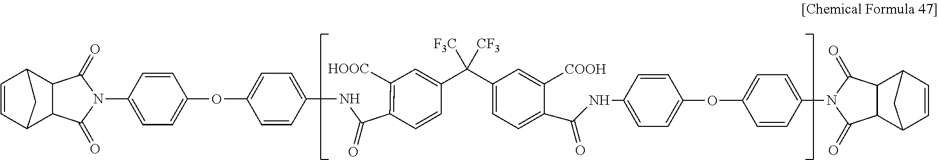

### Comparative Synthesis Example 4

18.7 g of 2,2′-bis(3-amino-4-hydroxyphenyl)hexafluoropropane (BHAF) and 1.6 g of 5-norbornene-2,3-dicarboxylic acid anhydride are dissolved in 117 g of N-methyl-2-pyrrolidone (NMP) in a 4-necked flask having an agitator, a temperature controller, a nitrogen gas injector, and a cooler while nitrogen gas is passed through the flask. Herein, the obtained solution includes a solid content of 15 wt %.

When the solid is completely dissolved, 7.27 g of pyridine is added thereto, and the mixture is heated up to 50° C. and then, agitated for 5 hours. When the terminal reaction is complete, the temperature is cooled down to room temperature, and a solution obtained by dissolving 9.4 g of 5,5′-(perfluoropropane-2,2-diyl)diisobenzofuran-1,3-dione in 37.6 g of N-methyl-2-pyrrolidone (NMP) is slowly added thereto in a dropwise fashion for 30 minutes. After the addition, the mixture is reacted at room temperature reaction and agitated for 3 hours.

Then, the temperature is decreased down to 0 to 5° C., and a solution obtained by dissolving 6.25 g of 4,4′-dioxybenzoylchloride in 45 g of N-methyl-2-pyrrolidone (NMP) is slowly added thereto in a dropwise fashion for 30 minutes. After the addition, the mixture is reacted for 1 hour at a temperature of 0 to 5° C. and then, heated up to room temperature and agitated for one hour, completing the reaction. The reaction mixture is put in water to produce a precipitate, and the precipitate is filtered, sufficiently washed with water, and dried at 80° C. under vacuum for greater than or equal to 24 hours, obtaining a polyamic acid-polyamide copolymer represented by the following Chemical Formula 48. Herein, a weight average molecular weight of the copolymer reduced to standard polystyrene by a GPC method is 10,500 g/mol, and polydispersity of the copolymer is 1.50.

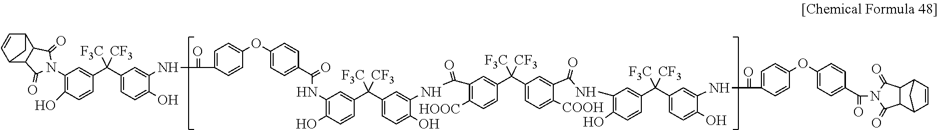

### Evaluation 1: Solubility for Tetramethylammonium Hydroxide (TMAH)

Solubility of the alkali soluble resins according to Synthesis Examples 1 to 6 and Comparative Synthesis Examples 1 to 4 is evaluated, and the results are provided in the following Table 1.

3 g of each alkali soluble resin according to Synthesis Examples 1 to 6 and Comparative Synthesis Examples 1 to 4 are added to 12 g of PGME/EL/GBL=7/2/1, preparing a solution including a solid of 20%. The solutions are respectively coated to be 2 μm thick on a 4-inch wafer with a spin-coater and baked at 120° C. for 100 seconds. The coated samples are cut to be 2 cm×2 cm and put in a 2.38 wt % tetramethylammonium hydroxide (TMAH) solution at 23° C., and then, a rate that the samples are dissolved therein is measured. The results are provided in the following Table 1.

TABLE 1

| | DR (A/s) |
|---|---|
| Synthesis Example 1 | 1050 |
| Synthesis Example 2 | 750 |
| Synthesis Example 3 | 2500 |
| Synthesis Example 4 | 1200 |
| Synthesis Example 5 | 1300 |
| Synthesis Example 6 | 980 |
| Comparative Synthesis | 1300 |
| Example 1 | |
| Comparative Synthesis | 400 |
| Example 2 | |
| Comparative Synthesis | 6200 |
| Example 3 | |
| Comparative Synthesis | 3000 |
| Example 4 | |

As shown in Table 1, Comparative Synthesis Example 2 including a polyimide repeating unit exhibits sharply deteriorated solubility, and Comparative Examples 3 and 4 including a part or whole of a polyamic acid repeating unit exhibit excessive solubility for TMAH, and accordingly, a photosensitive diazoquinone compound might be predicted to be excessively required. However, the polyhydroxyamide-polyimide copolymers according to Synthesis Examples 1 to 6 might be used to appropriately control solubility of an alkali soluble resin depending on a molecular weight, and the alkali soluble resin might have desired solubility and molecular weight by using carboxylic acid terminal end agent and the like as shown in Synthesis Examples 3 and 4.

### Manufacture of Positive Photosensitive Resin Composition

### Example 1

15 g of the copolymer according to Synthesis Example 1 is dissolved in 80 g of PGME/EL/g-GBL (7/2/1), and 0.05 g of a surfactant F-544 is added thereto and sufficiently dissolved therein by changing the addition amount of a photosensitive diazoquinone compound represented by the following Chemical Formula A. In addition, 5 wt % of thermal acid generator (PTSX, 2-methoxyethyl 4-methylbenzenesulfonate) represented by the following Chemical Formula 49 is added to the solution and sufficiently dissolved therein to measure a curing degree at 250° C. Then, the mixture is filtered with a 0.45 μm fluororesin filter, obtaining a positive photosensitive resin composition.

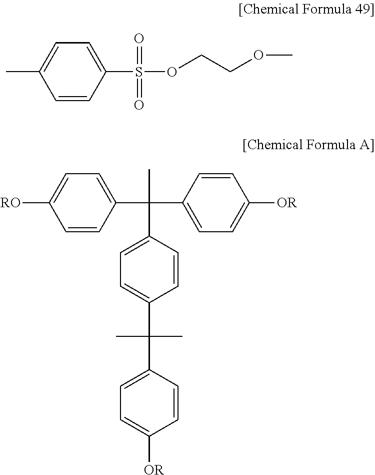

In the above Chemical Formula A, two out of three R's are represented as

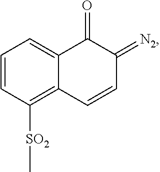

and the other one is hydrogen.

### Example 2

A positive photosensitive resin composition is prepared according to same method as Example 1 except for using the copolymer according to Synthesis Example 2 instead of the copolymer according to Synthesis Example 1.

### Example 3

A positive photosensitive resin composition is prepared according to the same method as Example 1 except for using the copolymer of Synthesis Example 3 instead of the copolymer of the Synthesis Example 1.

### Example 4

A positive photosensitive resin composition is prepared according to the same method as Example 1 except for using the copolymer of Synthesis Example 4 instead of the copolymer of Synthesis Example 1.

### Example 5

A positive photosensitive resin composition is prepared according to the same method as Example 1 except for using the copolymer of Synthesis Example 5 instead of the copolymer of Synthesis Example 1.

### Example 6

A positive photosensitive resin composition is prepared according to the same method as Example 1 except for using the copolymer of Synthesis Example 6 instead of the copolymer of Synthesis Example 1.

### Comparative Example 1

A positive photosensitive resin composition is prepared according to the same method as Example 1 except for using the copolymer of Comparative Synthesis Example 1 instead of the copolymer of Synthesis Example 1.

### Comparative Example 2

A positive photosensitive resin composition is prepared according to the same method as Example 1 except for using the copolymer of Comparative Synthesis Example 2 instead of the copolymer of Synthesis Example 1.

### Comparative Example 3

A positive photosensitive resin composition is prepared according to the same method as Example 1 except for using the copolymer of Comparative Synthesis Example 3 instead of the copolymer of Synthesis Example 1.

### Comparative Example 4

A positive photosensitive resin composition is prepared according to the same method as Example 1 except for using the copolymer of Comparative Synthesis Example 4 instead of the copolymer of Synthesis Example 1.

Sensitivity, film residue ratio, and curing degree of the positive photosensitive resin compositions according to Examples 1 to 6 and Comparative Examples 1 to 4 are evaluated, and the results are provided in the following Tables 2 to 4.

### Evaluation 2: Film Residue Ratio and Sensitivity

The positive photosensitive resin compositions according to Examples 1 to 6 and Comparative Examples 1 to 4 are respectively coated on an 8 inch wafer or an ITO substrate by using a spin-coater (1H-DX2, Mikasa Co., Ltd.) and heated on a hot plate at 120° C. for 100 seconds, forming each photosensitive resin film.

The photosensitive resin film is patterned by putting a mask having various sized patterns thereon, exposing them to light with a i-line stepper (NSR i10C, Mikon Corp.) by changing exposure time, dipping them in a 2.38 wt % tetramethylammonium hydroxide (TMAH) aqueous solution for 80 seconds at room temperature to remove the exposed part, and washing with pure water for 30 seconds. Subsequently, the obtained pattern is cured in an oxygen concentration of less than or equal to 1000 ppm at 250° C./40 min by using an electric furnace.

The film residue ratio (thickness after development/thickness before development, unit %) is calculated by using a film thickness change after the film thickness change after pre-baking, development, and curing is measured by using an equipment (ST4000-DLX, K-mac). Herein, the film residue ratio is calculated by using a constant thickness of 2.5 μm during the pre-baking.

The sensitivity is evaluated by measuring an exposure time taken to form a 10 μm L/S pattern with a line with of 1:1 after exposing and developing as an optimal exposure time.

(1) Film residue ratio when the photosensitive diazoquinone compounds are used in the same amount

TABLE 2

| | | | Photosensitive | |
|---|---|---|---|---|
| | | | diazoquinone | Film |
| | Film thickness (μm) | | (Chemical | residue |
| | Pre- | After | Formula A) | ratio |
| | baking | development | (phr) | (%) |
| Example 1 | 2.5 | 2.25 | 25 | 90 |
| Example 2 | 2.5 | 2.375 | 25 | 95 |
| Example 3 | 2.5 | 2.0 | 25 | 80 |
| Example 4 | 2.5 | 2.15 | 25 | 86 |
| Example 5 | 2.5 | 2.13 | 25 | 85 |
| Example 6 | 2.5 | 2.3 | 25 | 92 |
| Comparative | 2.5 | 2.125 | 25 | 85 |
| Example 1 | | | | |
| Comparative | 2.5 | 2.5 | 25 | 100 |
| Example 2 | | | | |
| Comparative | 2.5 | 0 | 25 | 0 |
| Example 3 | | | | |
| Comparative | 2.5 | 0 | 25 | 0 |
| Example 4 | | | | |

As shown in Table 2, developability of Comparative Examples 3 and 4 using an alkali soluble resin including a polyamic acid repeating unit might not be suppressed by using a photosensitive diazoquinone compound as a dissolution suppressor for TMAH in a common amount. On the other hand, Comparative Example 1 using an alkali soluble resin including a polyhydroxyamide repeating unit or Comparative Example 2 using an alkali soluble resin a polyimide repeating unit exhibit some dissolution suppression but are not as effective as Examples 1 to 6 using a repeating unit having various molecular weights and functional groups.

(2) Amount and sensitivity of photosensitive diazoquinone compound at a film residue ratio of 80%

TABLE 3

| | | | Photosensitive | |
|---|---|---|---|---|
| | | | diazoquinone | |
| | Film thickness (μm) | | (Chemical | Sensitivity |
| | Pre- | After | Formula A | L/S = 10 μm |
| | baking | development | (phr)) | (mJ/cm²) |
| Example 1 | 2.5 | 2.0 | 21 | 150 |
| Example 2 | 2.5 | 2.0 | 15 | 170 |
| Example 3 | 2.5 | 2.0 | 25 | 180 |
| Example 4 | 2.5 | 2.0 | 22 | 200 |
| Example 5 | 2.5 | 2.0 | 23 | 175 |
| Example 6 | 2.5 | 2.0 | 22 | 190 |
| Comparative | 2.5 | 2.0 | 23 | 220 |
| Example 1 | | | | |
| Comparative | 2.5 | 2.0 | 15 | 280 |
| Example 2 | | | | |
| Comparative | 2.5 | 0 | >60 | unmeasurable |
| Example 3 | | | | |
| Comparative | 2.5 | 0 | >60 | unmeasurable |
| Example 4 | | | | |

The amount of the photosensitive diazoquinone compounds is controlled to have a film residue ratio of 80% and thus, to form each organic insulation layer having the same thickness after development, and the results are provided in Table 3.

As shown in Table 3, sensitivity of Comparative Examples 3 and 4 including a polyamic acid repeating unit is unmeasurable, because the compositions are washed away in a TMAH solution even though a photosensitive diazoquinone compound is used in an amount of greater than or equal to 60 phr.

In addition, sensitivity of Comparative Examples 1 and 2 is measurable but is worse than Examples 1 to 6.

In other words, Examples 1 to 6 did not use a photosensitive diazoquinone compound in an excessive amount compared with Comparative Examples 1 to 4 but accomplish excellent sensitivity and film residue ratio.

### Evaluation 3: Curing Degree

The positive photosensitive resin compositions according to Examples 1 to 6 and Comparative Examples 1 to 4 are respectively coated on an 8 inch wafer or an ITO substrate by using a spin-coarter (1H-DX2, Mikasa Co., Ltd.) and heating the coated product on a hot plate at 120° C. for 100 seconds to form a photosensitive resin film.

The film is cured at 250° C. for 40 minutes in a curing equipment without an exposure process, and IR characteristic peaks before and after the curing are compared and converted into area %. The results are provided in the following Table 4.

TABLE 4

| | Curing Rate |
|---|---|
| | (%) |
| Example 1 | 92 |
| Example 2 | 92 |
| Example 3 | 90 |
| Example 4 | 91 |
| Example 5 | 94 |
| Example 6 | 92 |
| Comparative Example 1 | 70 |
| Comparative Example 2 | 100 |
| Comparative Example 3 | 80 |
| Comparative Example 4 | 75 |

As shown in Table 4, Examples 1 to 6 exhibit excellent curing degree compared with Comparative Examples 1, 3, and 4 except for Comparative Example 2 including a polyimide repeating unit having a 100% ring-closure.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims. Therefore, the aforementioned embodiments should be understood to be exemplary but not limiting the present invention in any way.

What is claimed is:

1. A positive photosensitive resin composition, comprising
(A) an alkali soluble resin including a repeating unit represented by the following Chemical Formula 1;
(B) a photosensitive diazoquinone compound; and
(C) a solvent: 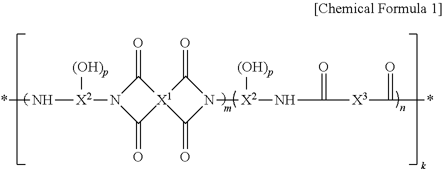
wherein, in the above Chemical Formula 1,
X¹, X² and X³ are the same or different and are each independently an aromatic organic group, a divalent to octavalent aliphatic organic group, or a divalent to octavalent alicyclic organic group,
m and n are the same or different and are each independently integers of 1 to 10,
k is an integer of 1 to 10,000, and
p is an integer of 0 to 6.

2. The positive photosensitive resin composition of claim 1, wherein the m and n are independently integers of 1 or 2.

3. The positive photosensitive resin composition of claim 1, wherein the alkali soluble resin is an alternating copolymer, a block copolymer, a random copolymer of polyimide-polyhydroxyamide, or a combination thereof.

4. The positive photosensitive resin composition of claim 1, wherein the alkali soluble resin is an alternating copolymer of polyimide-polyhydroxyamide.

5. The positive photosensitive resin composition of claim 1, wherein the alkali soluble resin has a weight average molecular weight of about 1,000 g/mol to about 20,000 g/mol.

6. The positive photosensitive resin composition of claim 1, wherein the solvent is N-methyl-2-pyrrolidone, γ-butyrolactone, N,N-dimethylacetamide, dimethylsulfoxide, diethylene glycoldimethylether, diethylene glycoldiethylether, diethylene glycoldibutylether, propylene glycolmonomethylether, dipropylene glycolmonomethylether, propylene glycolmonomethyl ether acetate, methyl lactate, ethyl lactate, butyl lactate, methyl-1,3-butylene glycol acetate, 1,3-butylene glycol-3-monomethylether, methyl pyruvate, ethyl pyruvate, methyl-3-methoxy propionate, or a combination thereof.

7. The positive photosensitive resin composition of claim 1, wherein the positive photosensitive resin composition further comprises an additive comprising a surfactant, a leveling agent, a thermal acid generator or a combination thereof.

8. The positive photosensitive resin composition of claim 1, wherein the positive photosensitive resin composition comprises:
about 5 parts by weight to about 100 parts by weight of the photosensitive diazoquinone compound (B), and
about 200 parts by weight to about 900 parts by weight of the solvent (C),
each based on about 100 parts by weight of the alkali soluble resin (A).

9. A photosensitive resin film formed by using the positive photosensitive resin composition of claim 1.

10. A display device comprising the photosensitive resin film of claim 9.
